(19) United States
(12) Patent Application Publication
(10) Pub. No.: US 2002/0050370 A1
(43) Pub. Date: May 2, 2002

(54) Data transmission system utilizing spread spectrum codes, receiving device suitable for such a system and synchronization method for such a system

(76) Inventor: Nabil Khalifa, Le Mans (FR)

Correspondence Address: U.S. Philips Corporation, 580 White Plains Road, Tarrytown, NY, 10591, US

(21) Appl. No.: 09/855,625

(22) Filed: May 15, 2001

(30) Foreign Application Priority Data
May 16, 2000 (FR) 0006227

(51) Int. Cl. H05K 9/00

(52) U.S. Cl. 174/35 R

(57) ABSTRACT

This data transmission system satisfies a specification of the type 3G TS 25.211 and, while using spread spectrum codes, is formed by at least a transmission part (10) for transmitting the data by using spread spectrum codes and at least a receiving part (20) for receiving said data. In this system first data are transmitted over the channel CPICH for a period of time that is relatively long, whereas second data are transmitted over the channel SCH for period of time that a relatively short. It is suggested that the second data be transmitted during the interruptions of the transmission of the first data, or also with an attenuation of this transmission.

### DESCRIPTION

The invention relates to a data transmission system utilizing spread spectrum codes in the form of at least a transmission part for transmitting data by using spread spectrum codes and at least a receiving part for receiving said data, according to which system first data are transmitted for a relatively long period of time, whereas second data are transmitted for a relatively short period of time.

The invention also relates to a receiving device suitable for such a system.

The invention further relates to a synchronization method acting on transmitted data by means of spread spectrum codes. This is better known by the name of CDMA.

The invention finds highly significant applications notably for telecommunications systems satisfying the specifications stated in the document 3G TS 25.211 published by:

<<3GPP Support Office Address>>

650, Route des Lucioles-Sophia Antipolis

06560 Valbonne-France.

According to these specifications, for obtaining the synchronization of the transmission parts and the receiving parts, two types of information are transmitted: a first type continuously transmitted over a CPICH channel (Common Control Channel) and a second type transmitted for a short part of the data channels over a synchronization channel called SCH.

When the transmission comes difficult, notably because of multiple paths covered by the transmission waves, the synchronization runs the risk of being no longer possible.

The present invention proposes a system of the type defined in the opening paragraph which permits to largely improve providing the synchronization for difficult conditions.

Therefore, such a system is characterized in that the second data are transmitted during a transmission attenuation of the first data.

It is to be noted that this attenuation may be there until the transmission of the first data has completely stopped.

A synchronization method for data transmitted by means of spread spectrum codes is characterized in that transmission interruptions of the first data are created for transmitting the second data.

The idea of the invention thus comprises attenuating or stopping for a short instant the transmission of the first data which practically causes no unwanted influence whatever on the synchronization process. Furthermore, there is no influence at all on the estimate of the channel which consists of establishing its amplitude and phase characteristics. This short interruption thus avoids the interference of the second data, which enables the receiving parties to better discern them among the received signals. Actually, it is to be considered that the spread spectrum codes are not always perfectly mutually orthogonal.

These and other aspects of the invention are apparent from and will be elucidated, by way of non-limitative example, with reference to the embodiment(s) described hereinafter.

In the drawings:

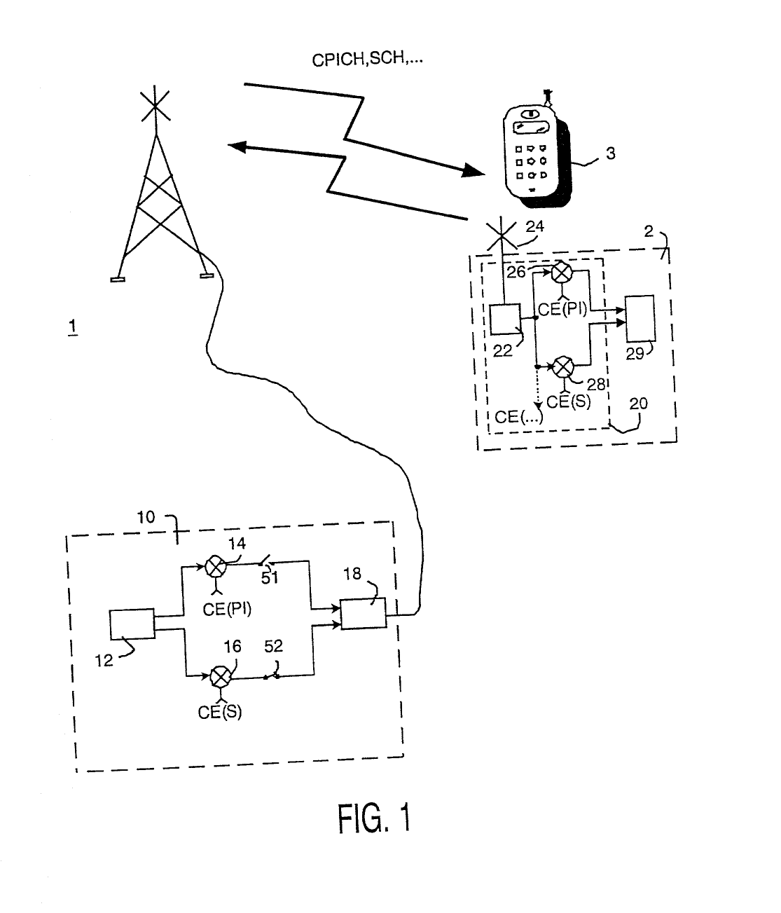

FIG. 1 shows a system according to the invention,

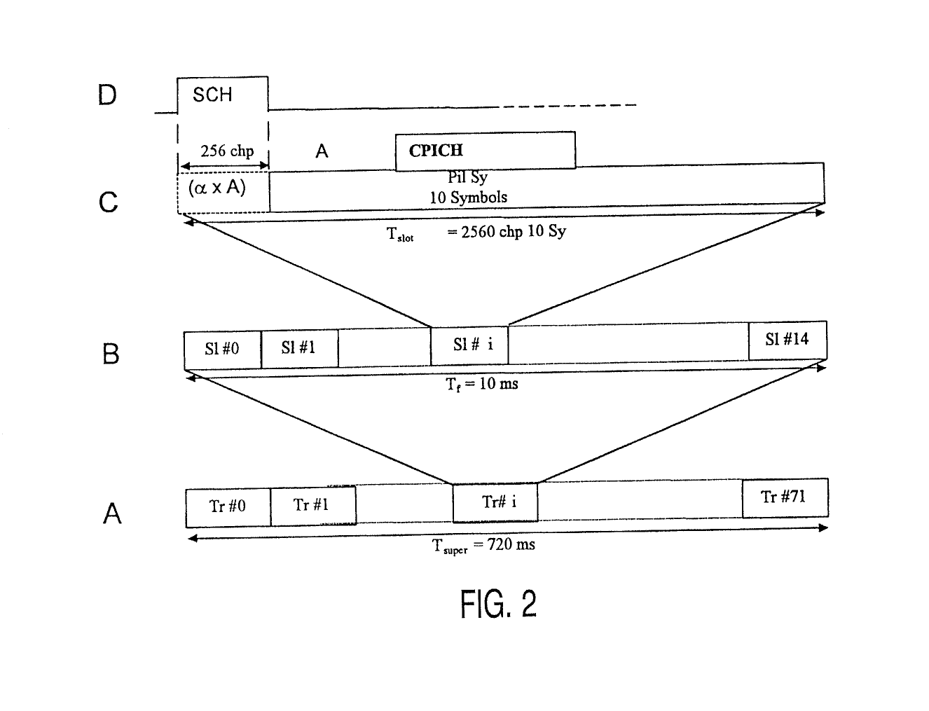

FIG. 2 shows a timing diagram explaining the organization of the channel transmission frames,

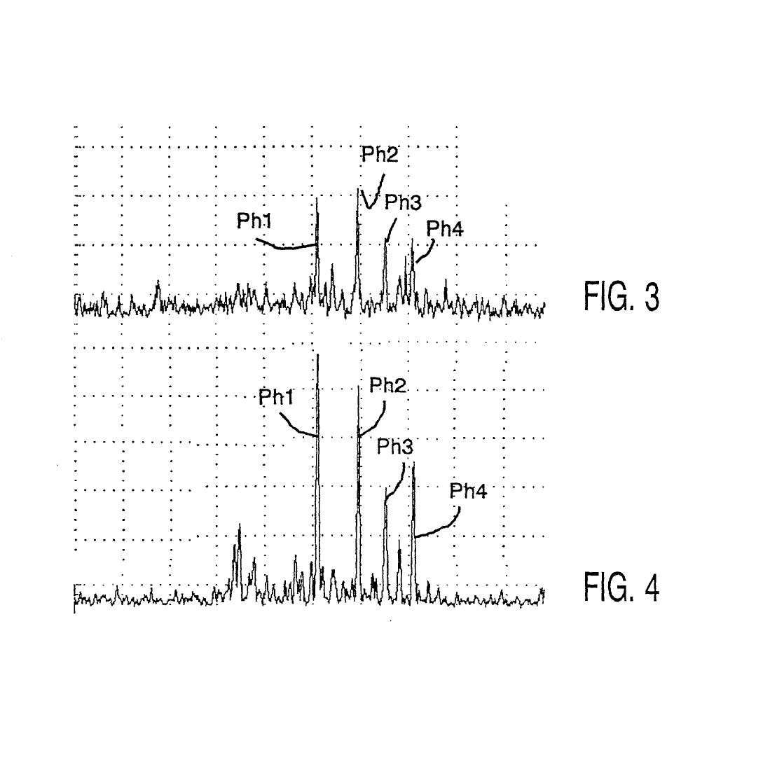

FIG. 3 shows the shape of the received signals without the implementation of the invention and

FIG. 4 shows the shape of the received signals with the implementation of the invention.

In FIG. 1 is shown a system according to the invention. Reference 1 indicates a base station and the references 2 and 3 mobile stations. The base station comprises a transmission part of which a block 10 is shown in FIG. 1. This block comprises a synchronizing data generator 12. This generator produces the data for the channels CPICH and SCH defined in the specification cited above. These channels are transmitted by using spread spectrum codes CE(PI) for the channel CPICH for long periods of time and the code CE(S) for the channel SCH for rather short periods of time. These codes CE(PI) and CE(S) are multiplied by the multipliers 14 and 16 respectively, to the data streams of the channels CPICH and CE(S) produced by the generator 12. As these codes CE(PI) and CE(S) are practically mutually orthogonal, it is possible to combine them on transmission, which is done in circuit 18.

The receiving part 20 of the mobile station 2 comprises a receiving circuit 22 which processes the signals received by the antenna 24 and produces a data stream which may be selected by using the decorrelators 26 and 28 and others for each of the transmitted channels. These decorrelators operate based on spreading codes assigned to each of these channels, notably the codes CE(PI) and CE(S) cited above. Other codes CE( . . . ) are used for the other channels. The data thus demultiplexed are fed to a processing circuit 29 for a normal use of the mobile.

FIG. 2 explains the frame organization of the transmitted signals in accordance with the specification cited above.

At A is represented the superframe of the channel CPICH which lasts: Tₛᵤₚₑᵣ=720 ms and which comprises 72 frames denoted Tr#0 to Tr#71.

At B is represented the structure of said frames which is in the form of time slots referred to as S1#0 to S1#14 each of which lasting T_{f}=10 ms.

At C is shown the structure of these time slots which contain symbols, the symbols are combined with brief binary elements (chp) forming the spreading code (CE(PI)). These brief binary elements are better known by the English name of chip.

At D is represented the transmission over the channel SCH of synchronization information.

In accordance with the invention, when there is a transmission on the channel SCH, there is an attenuated transmission or this transmission is lost on the channel CPICH whose nominal value is A; this is indicated by α×A at the line C. This duration is equal to a symbol or 256 chp.

In FIG. 1 is represented by the switches 51 and 52 this transmission/no-transmission function. Thus the switch 51 is open for prohibiting any transmission on the channel CPICH when there is a transmission on the channel SCH, the switch 52 is thus closed.

FIG. 3 shows the shape of the received signal transmitted by the channel SCH, without the measures recommended by the invention being applied. This signal is received by borrowing four main paths Ph1, Ph2, Ph3 and Ph4.

FIG. 4 shows the shape of this same received signal, transmitted by the channel SCH, by applying the measures recommended by the invention, while for the rest all matters are equal. The effect obtained by the invention is thus made obvious. The peaks relating to the various paths Ph1, Ph2, Ph3 and Ph4 are much more apparent than those obtained without implementing the invention.

1. A data transmission system utilizing spread spectrum codes in the form of at least a transmission part for transmitting data by using spread spectrum codes and at least a receiving part for receiving said data, according to which system first data are transmitted for a relatively long period of time, whereas second data are transmitted for a relatively short period of time, characterized in that the second data are transmitted during a transmission attenuation of the first data.

2. A transmission system as claimed in claim 1, characterized in that the attenuation value is equal to stop of the transmission.

3. A transmission system as claimed in claim 1 satisfying a specification of the type 3G TS 25.211, characterized in that the first data relate to the channel CPICH and the second data to the channel SCH.

4. A receiving device suitable for a system as claimed in claim 1, 2 or 3, comprising a receiving part, characterized in that it comprises decorrelators operating with said spreading codes for re-assembling the transmitted data.

5. A synchronization method influencing data transmitted by means of spread spectrum codes implemented in a system as claimed in claim 1 or 2 or 3, in which the first data are transmitted for a relatively long period of time whereas the second data are transmitted for a relatively short period of time, characterized in that transmission attenuations of the first data are created to transmit the second data.

6. A synchronization method as claimed in claim 5, characterized in that the value of the attenuation is equal to stop of the transmission.
